(19) United States
(12) Patent Application Publication
(10) Pub. No.: US 2009/0280592 A1
(43) Pub. Date: Nov. 12, 2009

(54) Nanoparticle structure and manufacturing process of multi-wavelength light emitting devices

(75) Inventors: Wei-Kuo CHEN, Hsinchu City (TW); Wen-Cheng KE, Yuanlijhen Township (TW)

Correspondence Address: BUCKNAM AND ARCHER, 1077 NORTHERN BOULEVARD, ROSLYN, NY, 11576, US

(73) Assignee: National Chiao-Tung University

(21) Appl. No.: 12/455,183

(22) Filed: May 29, 2009

Related U.S. Application Data
(62) Division of application No. 11/442,471, filed on May 26, 2006.

(30) Foreign Application Priority Data
Nov. 11, 2005 (TW) 094139600

(51) Int. Cl. H01L 33/00

(52) U.S. Cl. 438/35; 438/47; 977/773; 438/478; 257/E33.061; 257/E33.005

(57) ABSTRACT

A structure of multi-wavelength light emitting device comprises multi-stacked active layer structure. Each stacked layer comprises lower energy bandgap well 4 and higher energy bandgap barrier layer 3 wherein at least one stacked layer in the device contains nanoparticles. As a result, the emitting wavelengths of the multi-stacked active layer structure consist parts (or all) of the emitting wavelengths come from the stack layers containing nanoparticles, and parts (or all) of the emitting wavelengths come from the stack layers not containing nanoparticles. In another embodiment, parts (or all) of the emitting wavelengths of the multi-stacked active layer structure can be also used to trigger one or more phosphorescences from the phosphors, thus the emitting wavelengths of such a phosphors converted light emitting device may come partially from the multi-stacked active layer itself and partially (or all) from the phosphors.

### FIELD OF THE INVENTION

The present relates to a novel structure of light emitting device, particularly to a structure consisting of nanoparticles embedded in active layer, and manufacturing process thereof. The structure is useful in the production of any optoelectronic semiconductor devices with hetero junctions.

### DESCRIPTION OF THE RELATED PRIOR ART

According to the research about light sources in energy saving and environmental protection, light emitting diode has become particularly attractive due to its low power consumption.

In view of the current white light emitting diodes and manufacturing method, there are three main categories comprising: (1) complementary dichroism wherein white light is hybridized by triggering yellow phosphor particles with blue light form light emitting diode; (2) UV-LED pumping phosphors wherein white light is hybridized by triggering RGB phosphor particles with UV light from light emitting diode; and (3) three primary color light hybridization wherein white light is hybridized by stacking light emitting diodes of red, green and blue colors.

The theoretical light emitting efficiency of complementary dichroism, is as high as 400 lm/W, calculated by MacAdam in 1950. However, the white light generated by complementary dichroism is not applicable for full color displaying of objects due to the poor color rendering. Therefore, it is applied outdoor and industrially rather than indoor lighting such as museum, office and desktop. Exemplary white light sources using complementary dichroic hybridization were disclosed in U.S. Pat. No. 5,998,925, U.S. Pat. No. 6,069,440 and TW 383,508 issued to Nichia, in which white light emitting diodes are made of yttrium aluminum garnet phosphor particles and nitride diodes, and blue light emitting diodes (460 nm InGaN) are used to trigger yellow YAG phosphor particles coated thereon, so that the emitted yellow light is complementary to the primary blue light to generate white light. Although white light emitting diodes made of blue chips and yellow phosphor particles are well developed currently, there are problems to be solved. Firstly, emitting wavelength shifting and intensity variation of blue chips and phosphor coating thickness influence the homogeneity of white light, since color combination is essentially dominated by blue light chips (which normally results in bluish in the center and yellowish in the periphery). In addition, problems relating to high color temperature and low color rendering cause international major manufacturers to develop other methods for manufacturing white light emitting diodes.

Method of hybridizing white light by triggering RGB phosphor particles with UV light from light emitting diode was proposed by Thornton in 1971, in which white light with high color rendering is generated with trichroic hybridization (450, 540 and 610 nm). High color rendering prevents color distortion of objects caused by the generated white light due to lack of some wavelength bands, therefore is suitable to both indoor and outdoor lighting. Further, General Electric proposed, in U.S. Pat. No. 6,522,065, that the color of the white light generated by UV-LED pumping phosphors is completely controlled by the phosphor particles with the use of A₂₋₂ₓNa₁₊ₓEₓD₂V₃O₁₂ as phosphor particles, wherein A is selected from any one of Ca, Ba, Sr, or the combination thereof, E is selected from any one of Eu, Dy, Sm, Tl, Er, or the combination thereof, and D is selected from either of Mg and Zn, or the combination thereof; the color is controlled by adjusting ratio of active agent.

The currently major developed method relates to white light emitting diodes consisting of UV LED pumping RGB phosphor particles. However, issues like effective promotion of light emitting efficiency of UV LED, development of UV resistant packing materials, combination of wavelength bands, and environmental contamination of the phosphors need to be solved for it future development.

According to the Opto-electronics Industry Association predicted that the luminous efficiency of white LED would be arrived at 200 lm/W in 2020. The electrical luminous efficacy for white LED ε_{e,white}[lm/Wₑ] can be represented by WPE(T, I)×{η_{QD}×ηₚₕₒₛ(T)×ε_{o,phos}[lm/Wₒ]}×η_{pkg} where η_{pkg} is package efficiency, ηₚₕₒₛ(T) is phosphor quantum efficiency, η_{QD} is quantum deficit in phosphor (Stokes' shift), ε_{o,phos} is optical luminous efficacy of phosphor/LED blend and WPE(T, I) is wallplug efficiency. Wallplug efficiency is the amount of light power produced compared to the electrical power applied. High wall-plug efficiency can be achieved by maximizing the total efficiency of the device. The total efficiency of the device is a product of the various efficiencies of the device including the internal quantum, injection, and light extraction efficiencies (i.e. WPE(T, I)=ηᵢₙₜ×ηᵥ×η_{extract}, wherein ηᵢₙₜ indicates internal quantum efficiency, ηᵥ indicates electrical efficiency and η_{extract} indicates extraction efficiency) The first two parameters depend on the material quality of the device (epitaxial growth and electronic band structure) while the light extraction efficiency depends on the geometry and all the light absorption present in the device.

Reference from Lumiled reports that to obtain the electrical luminous efficacy of 200 lm/W for white LED fabricated by blue LED+phosphors, assume the optical luminous efficacy ε_{o,phos}[lm/Wₒ]≈330 lm/W, when η_{QD}=80%, ηₚₕₒₛ(25° C.)>95%. The WPE(T, I)×η_{pkg} must exceed 80% at appropriate temperature and drive. Otherwise, for the white LED fabricated from UV LED+RGB phosphors, assume εₚₕₒₛ[lm/Wₒ]<300 lm/W, when η_{QD}=70% (380 nm), ηₚₕₒₛ(25° C.)>95% (guess). The WPE(T, I)×η_{pkg} must exceed 100% at appropriate temperature and drive. However, for the white LED fabricated from three primary color chips, assume ε_{o,phos}[lm/Wₒ]<3000 lm/W, where η_{QD}=100%, ηₚₕₒₛ(25° C.)=100%. The WPE(T, I)×η_{pkg} is only 67% at appropriate temperature and drive.

WPE(T, I)×η_{pkg} fitting into theoretical calculation used in the tri-chip primary color hybridization is 67%, which is easier to match the requirement of high light emitting efficiency comparing to 80% of directly triggering yellow phosphor particles with blue light from light emitting diode, and 100% of UV-LED pumping phosphors. The main reason that the WPE of these manufacturing processes of white light emitting diode differ is directed to energy transformation efficiency, i.e., Stoke's energy loss. It is not necessary to consider energy transformation efficiency, which is 80% for triggering yellow phosphor particles with blue light emitting diode and 70% for UV-LED pumping phosphors, in tri-chip primary color hybridization, thus high light emitting efficiency is easier to achieve. For example, it is mentioned in U.S. Pat. No. 6,686,691 issued to Lumileds that white light is hybridized with the primary color bulbs; and in U.S. Pat. No. 6,234,645 issued to Philips that white light is hybridized with three or more LEDs to achieve light emitting efficiency of 40 lm/W.

All the mentioned conventional manufacturing processes for white light emitting diodes relate to the structure using quantum well as active layer, as shown in FIG. 1. Quantum well essentially consists of higher energy barrier layer and lower energy well layer. Under applied forward bias, minority carriers are injected into lower energy well layer, and emit light through radioactive recombination by confinement of barrier layer. The radioactive recombination rate can be represented by equation R=Bnp, wherein B is the recombination factor, n and p are carrier concentrations of electron and hole, respectively. Therefore, higher carrier concentration in the well layer increases recombination rate to obtain higher light emitting efficiency of LED. However, since no proper lattice-matched substrate 1 has been found for current blue and green light emitting diodes with III-nitride as film material, dislocation with density as high as 10⁸˜10⁹ cm⁻² has occurred. The dislocations normally penetrate through quantum well active layer and result in non-radioactive recombination centers therein to reduce internal quantum efficiency, which lowers light emitting efficiency of LED.

### SUMMARY OF THE INVENTION

In order to effectively reduce non-radioactive recombination caused by dislocations inside quantum well, and to elevate light emitting efficiency of LED, the present invention provides a growing process of nanoparticle structure; in particular high density of nanoparticles, in multi-stacked active layer to effectively elevate light emitting efficiency of LED.

The reason for employing high density of mamoparticle structure in multi-stacked active layer is to increase the possibility of carriers to fall into nanoparticles and elevate radiactive recombination when the density of nanoparticle is higher than that of dislocation, i.e., the distance between nanoparticles is smaller than that between dislocations, so that light emitting efficiency of LED is effectively elevated.

In the multi-stacked active layer structure where above-described nanoparticles embedded, the quantum confinement effect are enhanced when atom quantity in the nanoparticles decreases to a specific amount, i.e., the size of nanoparticles are smaller than exciton Bohr radius, accordingly electron orbital energy levels are discontinuous, and their energy levels are blue shifted to higher energy levels, hence shorter wavelengths. Therefore, emitting wavelengths of nanoparticles can be controlled by arranging the geometric size of the nanoparticles. Due to the separation of energy levels, the carriers at different energy levels can recombine with each other to emit light with various wavelengths, so that single nanoparticle is capable of emitting one or more wavelengths.

An object of the present invention is to effectively elevate light emitting efficiency of LED by providing a structure with nanoparticles embedded in multi-stacked active layer, which obtains light with the red, green and blue, so called “three primary colors” from single LED by designing composition and size of nanoparticles in multi-stacked active layer of the single LED, accordingly white light emitting diodes are manufactured. The described white light emitting diodes manufactured with nanoparticle structure in multi-stacked active layer match the requirements of high light emitting efficiency, high color rendering and low cost.

In the nanoparticle-containing multi-stacked active layer structure of LED in the present invention, the elemental composition and geometric size thereof are directly controlled to modify emitting wavelengths so that white light is hybridized with the primary colors. Alternatively, phosphor is used additionally to modify emitting wavelengths to be suitable to hybridize white light with high color rendering.

Referring to FIG. 2(a), the structure as the multi-stacked active layer of LED in the present invention comprises multi-stacks among substrate 1, buffer layer 2 and conductive layer 8, and each stacked layer comprises lower energy well layers 4 and higher energy barrier layers 3. It is characterized that at least one well layer 4 is nanoparticle structure capable of emitting light either with multicolor wavelengths, or single color wavelength. FIG. 2(b) shows the emitting wavelengths of multi-stacked active layer with three primary colors combined by three different emitting wavelengths of nanoparticle in separate well layer (λ₁, λ₂ and λ₃). In FIG. 2(c), the emitting wavelengths of each stacked layer could be combined the emitting wavelengths with well (λ), nanoparticles (λ₃) and emitting wavelengths of ground state (λ₃₋₁) and first excited state (λ₃₋₂) nanoparticles. The structure as the multi-stacked active layer of LED in the present invention further comprises phosphor capable of emitting phosphorescence with one or more wavelengths. The combination of wavelengths of light from multi-stacked active layer themselves and of light from the phosphor triggered by said light produces multi-wavelength light emitting devices. Nanoparticles in well layer can be grown among thereof, or above or below the interface between well layer and barrier layer.

In the above-described structure as the multi-stacked active layer of LED in the present invention, the combination of the emitting wavelength of the nanoparticles in said multi-stacked active layer structure and phosphorescence from phosphor is suitable to hybridize white light, wherein the desired wavelength is obtained by controlling elemental composition or size of nanoparticles through adjustment of growing parameters. In addition, the emitting wavelength of the nanoparticles embedded in said multi-stacked active layer structure may be within UV region to trigger phosphor with complementary color property to hybridize white light. Further, the emitting wavelength of the nanoparticles in said multi-stacked active layer structure may be within UV region to trigger phosphor with the primary colors or multicolor phosphorescence wavelength to hybridize white light. Furthermore, the emitting wavelength of the nanoparticles in said multi-stacked active layer structure may be of one or more visible wavelengths to trigger phosphor with one or more phosphorescence wavelengths, wherein triggering wavelengths is capable of combining phosphorescence wavelengths to hybridize white light with complementary dichroism or the primary colors.

The above-described structure as the multi-stacked active layer of LED in the present invention is stacked layers partially (or completely) comprising nanoparticles and partially (or completely) not comprising nanoparticles. The multi-stacked active layer of complementary dichroism, wherein the desired complementary dichroism to hybridize white light is obtained by controlling elemental composition or size of well and nanoparticles without use of external phosphor.

Preferably, the above-described structure as the multi-stacked active layer of LED in the present invention is stacked layers partially (or completely) comprising nanoparticles and partially (or completely) not comprising nanoparticles. The multi-stacked active layer of LED with three or more kinds of emitting wavelengths, wherein the primary colors necessary to hybridize white light is obtained by controlling elemental composition or size of well and nanoparticles, or white light with continuous spectrum is hybridized with multichroism.

The materials useful in the multi-stacked active layer of LED in the present invention are selected from GaAs, InAs, InP, InSb, GaSb, InAGaN, InN, AlN, ZnSe, ZnTe, CdSe, CdTe, HgTe, HgSe, SiGe, SiC, InₓGa₁₋ₓN, InₓGa₁₋ₓP, InₓGa₁₋ₓAs, AlₓIn₁₋ₓN, AlₓIn₁₋ₓP, AlₓIn₁₋ₓAs, AlₓGa₁₋ₓN, AlₓGa₁₋ₓP, AlₓGa₁₋ₓAs, ZnₓCd₁₋ₓSe, ZnₓCd₁₋ₓTe, (AlₓGa₁₋ₓ)_{y}In_{1-y}N, (AlₓGa₁₋ₓ)_{y}In_{1-y}P, wherein 0<x<1; 0<y<1. The thickness of the lower energy well layer of the multi-stacked structure active layer is 0.3 nm˜1 μm, and that of higher energy barrier layer is 1 nm˜1 μm. The density of the emitting nanoparticle in the active layer ranges 10³˜10¹³ cm⁻² or higher, the thickness thereof ranges 0.3˜100 nm, and the width thereof ranges 0.3˜500 nm.

In addition, the phosphor useful in said light emitting devices may be yellow: Y₃Al₅O₁₂:Ce³⁺, yellow: Y₃Al₅O₁₂:Eu²⁺, yellow: Y₃Al₁₅O₁₂:Eu²⁺, red: SrSiAl₂O₃N₂:Eu²⁺, red: SrS:Eu²⁺, red: Gd₂O₃S:Eu³⁺, red: SrS:Eu²⁺, green: SrAlSCISi:Eu, green: SrGa₂S₄:Eu²⁺, green: SrGa₂S₄:Eu²⁺, blue: SCAP, blue: BaMgAl₁₀O₁₇:Eu²⁺, etc.

Further, in the above-described multi-stacked active layer of LED in the present invention, trimmed reverse pyramid, surface roughing and flip-chip stacking are useful to elevate light emitting efficiency of the devices.

With the use of the multi-stacked active layer structure unity in the present invention, instead of three chips primary color LEDs, the requirements of high color rendering, high light emitting efficiency and low cost are matched by single LED. To hybridize white light with the primary colors improves low color rendering occurred in the white light generated by triggering yellow phosphor particles with blue light emitting diode. Besides, with the use of nanoparticle active layer structure, the non-radioactive recombination caused by dislocations inside quantum well is supressed, and the light emitting efficiency is elevated. An object of the present invention is to generate white light with single LED which is of nanoparticle structure as the multi-stacked active layer.

The manufacturing process of the above-described multi-stacked active layer structure of LED at least comprises: (1) providing a substrate 1; (2) growing n or p type buffer layer 2 on the substrate 1; (3) growing barrier layer 3; (4) growing nanoparticles with first emitting wavelength 5 on well layer 4 in the first quantum well; (5) growing another barrier layer 3; (6) growing nanoparticles with second emitting wavelength 6 on well layer 4 in the second quantum well; (7) growing another barrier layer 3; (8) growing nanoparticles with third emitting wavelength 7 on well layer 4 in the third quantum well; (9) growing another barrier layer 3; (10) finally, growing p or n type conductive layer 8 at elevating temperature. Further, the processing of steps (4) to (8) depends on the desired wavelength and combination of the type of multi-stacked active layer of multi-wavelength LED in the present invention. With the use of the manufacturing process of structure as active layer of LED in the present invention, a manufacturing process of phosphor emitting phosphorescence with one or more wavelengths is provided, which comprises a step of further growing phosphor subsequent to the above-described step (10).

Conventional growing process of nanoparticles hereto is based on SK mode, wherein lattice mismatch between buffer layer and epilayer must be larger than 2% to transform growing mode of nanoparticles in epilayer from two dimensionally planar to three dimensionally island-like (or pyramid type). This process for transforming growing mode has been widely used to nanoparticle for growing Group III-V or II-VI compound, such as InAs/GaAs, ZnTe/ZnSe, etc. semiconductors with lattice mismatch of 5˜7%. In addition, JP 10,289,996 and JP 9,283,737 issued to Nakada Yoshiaki et al. disclosed a SK mode based method for growing InAs nanoparticles on GaAs buffer layer. When nanoparticles are grown in multiple quantum wells active layer of LED with SK mode, they are only grown on higher energy barrier layer with lattice mismatch >2%. Therefore, the structure design of active layer is limited, and both the selection on materials of active layer and modification range of emitting wavelength of LED are reduced.

The growing method of nanoparticles may be a periodic flow rate modulation epitaxy process as described in U.S. patent application Ser. No. 11/005,547, filed on Jun. 12, 2004 by the present inventor, and related documents from the present inventor published in Japanese Journal of Applied Physic, Vol. 43, No. 6B, 2004, pp. L780˜783, June, 2004, Wei-Kuo Chen et al., “Formation of Self-organized GaN Dots on Al_{0.11}Ga_{0.89}N by Alternating Supply of Source Precursors”, wherein a process of growing nanoparticles as multiple quantum wells active layer structure of LED was disclosed. The process can be conducted on materials with low lattice constant mismatch and even with same lattice constant to grow nanoparticles, so that the selection on materials of multiple quantum wells active layer structure of LED is various to expand modification range of emitting wavelength. It is also possible to directly grow nanoparticle structure inside lower energy well layer 4 to elevate light emitting efficiency. Thereore, unexpected effects are obtained through use of the nanoparticle structure grown by the periodic flow rate modulation epitaxy process of the invention.

Therefore, in the prevent invention, a structure of multi-wavelength light emitting device, which comprises multi-stacked active layer structure and phosphors, and each stacked layer comprises lower energy bandgap well 4, higher energy bandgap barrier layer 3 and at least one stacked layer with nanoparticle structure capable of emitting single, dichroic or three or more color wavelengths, so that parts (or all) of the emitting wavelengths come from the stack layers containing nanoparticles, and parts (or all) of the emitting wavelengths come from the stack layers not containing nanoparticles; wherein some (or all) of the first emitting wavelengths of the multi-stacked active layer structure are used to trigger one or more phosphorescences from the phosphors called the second emitting wavelengths, thus the wavelengths of the light emitting device consist of wavelengths from the multi-stacked active layer themselves and phosphorescences from the phosphors.

### BRIEF DESCRIPTION OF THE DRAWING

FIG. 1 shows a structure of a conventional light emitting diode with multiple quantum wells as active layer.

FIG. 2 (a) shows the structure of light emitting diode in the present invention, wherein white light is hybridized with the primary color wavelengths by using nanoparticle-containing MQWs structure as active layer; (b) shows related energy bands; and (c) is a schematic view showing emitting wavelength could be from well, separate energy levels and emitting wavelengths of nanoparticles with quantum effect.

FIG. 3 shows the atomic force microscopy images (5 μm×5 μm) of GaN nanoparticles at different TMGa flow rates: (a) AlGaN buffer layer 2; TMGa flow rate at (b) 2.21×10⁻⁵ mole/min; (c) 2.65×10⁻⁵ mole/min; and (d) 3.31×10⁻⁵ mole/min.

FIG. 4 is a low temperature photoluminescence spectra of GaN nanoparticles formed at different TMGa flow rates: (a) AlGaN buffer layer; TMGa flow rate at (b) 2.21×10⁻⁵ mole/min; (c) 2.65×10⁻⁵ mole/min; and (d) 3.31×10⁻⁵ mole/min.

FIG. 5 (a) shows the nanoparticle-containing MQWs active layer of light emitting diode with single wavelength in the present invention; and (b) shows related energy bands.

FIG. 6 (a) shows the nanoparticle-containing MQWs active layer of light emitting diode in the present invention, wherein complementary dichroism is obtained by combination the emitting wavelength of well and nanoparticles; and (b) shows related energy bands.

FIG. 7 (a) shows the nanoparticle-containing MQWs active layer of light emitting diode in the present invention, wherein complementary dichroism is used; and (b) shows related energy bands.

FIG. 8 (a) shows the nanoparticle-containing MQWs active layer of light emitting diode with multi-wavelengths in the present invention, wherein nanoparticles of complementary dichroism are grown in the same well layer simultaneously; and (b) shows related energy bands.

FIG. 9 (a) shows the nanoparticle-containing MQWs active layer with wetting layer as active layer of light emitting diode in the present invention; and (b) shows related energy bands.

FIG. 10 (a) shows the nanoparticle-containing MQWs active layer with interface state as active layer of light emitting diode in the present invention; and (b) shows related energy bands.

FIG. 11 (a) shows the nanoparticle-containing MQWs active layer of light emitting diode with primary color RGB wavelengths in the present invention; and (b) shows related energy bands.

FIG. 12 (a) shows the nanoparticle-containing MQWs active layer of light emitting diode with multi-wavelengths in the present invention, wherein nanoparticles with the wavelengths including primary color RGB are grown in the same well layer simultaneously; and (b) shows related energy bands.

FIG. 13 (a) shows the nanoparticle-containing MQWs active layer of light emitting diode with multi-wavelengths in the present invention; and (b) shows related energy bands.

FIG. 14 is a schematic view showing separate energy levels and related emitting wavelengths of different sized InGaN nanoparticles with quantum effect.

FIG. 15 shows a multi-wavelength phosphor converted LED pumped by UV light source. (a) phosphors with complementary dichroism; and (b) phosphors with the primary colors RGB.

FIG. 16 shows a multi-wavelength phosphor converted LED pumped by visible light source. (a) shows a LED structure wherein nanoparticle-containing LED with an triggering wavelength (λ₁) is used to trigger phosphors with a phosphorescence wavelength (λ₂); (b) shows a LED structure wherein nanoparticle-containing LED with an triggering wavelength (λ₁) is used to trigger phosphors with two phosphorescence wavelengths (λ₂ and λ₃); and (c) shows a light emitting device structure wherein nanoparticle-containing LED with two triggering wavelengths (λ₁ and λ₂) is used to trigger phosphors with a phosphorescence wavelength (λ₃).

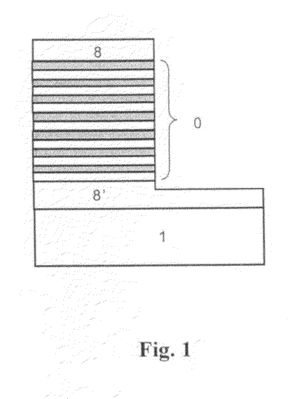

### Wherein,

0 denotes multiple quantum wells,

1 denotes substrate,

2 denotes n type buffer layer,

4 denotes barrier layer,

4 denotes well layer with emitting wavelength λ,

4a denotes wetting layer,

5 denotes nanoparticles with first emitting wavelength,

6 denotes nanoparticles with second emitting wavelength,

7 denotes nanoparticles with third emitting wavelength,

8 denotes p type conducting layer,

8′ denotes n type conducting layer,

9 denotes nanoparticles with first and second emitting wavelengths,

10 denotes nanoparticles with first, second and third emitting wavelengths,

11 denotes nanoparticles with fourth emitting wavelength,

12 denotes nanoparticles with fifth emitting wavelength,

13 denotes nanoparticles with sixth emitting wavelength,

14 denotes nanoparticles with seventh emitting wavelength,

15 denotes phosphors with complementary dichoric wavelengths,

16 denotes phosphors with the primary color phosphorescence

17 denotes nanoparticles with first triggering wavelength,

18 denotes nanoparticles with second triggering wavelength,

19 denotes phosphors with first phosphorescence wavelength (λ₁),

20 denotes phosphors with second and third phosphorescence wavelength (λ₂ and λ₃),

21 denotes emitting wavelength of ground state nanoparticles λ₃₋₁,

22 denotes emitting wavelength of excited state nanoparticles λ₃₋₂,

23 denotes emitting wavelength of wetting layer λ₁₋₁,

24 denotes emitting wavelength of interface state λ₁₋₂.

### DETAILED DESCRIPTION OF THE INVENTION

Firstly, GaN nanoparticles successfully grown on AlGaN buffer layer with low lattice mismatch of 0.25% by periodic flow rate modulation epitaxy process of the invention are described. However, the manufacturing process of nanoparticle structure as multiple quantum wells active layer described later is not limited thereto.

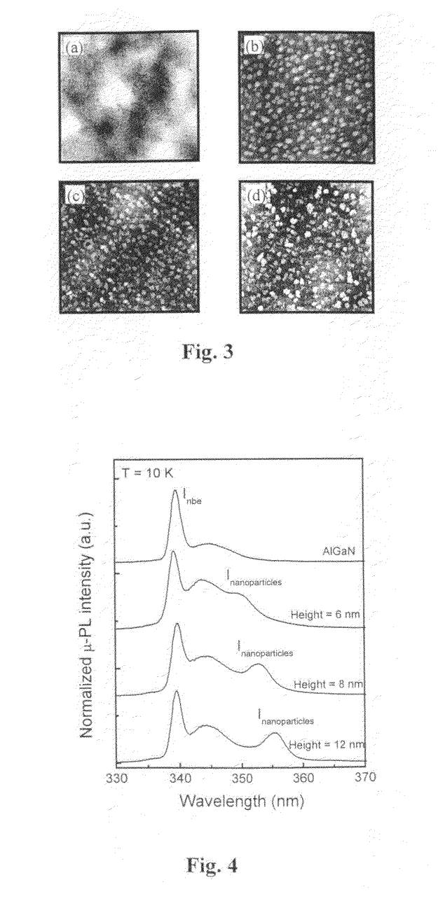

FIG. 3 is a microphotograph showing atomic force microscopy (AFM) images of GaN nanoparticles grown by periodic flow rate modulation epitaxy process with different TMGa reaction gases flow rates. The TMGa flow rate growing parameters are 2.21×10⁻⁵, 2.65×10⁻⁵, and 3.31×10⁻⁵ mole/min, respectively. It is known from FIG. 3 that the height/width of the nanoparticles are 6/200, 8/160 and 12/220 nm, respectively. A depositing of same Al composition as AlGaN buffer layer 2 and thickness of 30 nm is further deposited on the GaN nanoparticles for optical properties measurements thereof. It is found in FIG. 4 that, when the size of GaN nanoparticles decreases, blue shifting of GaN nanoparticle related peaks is observed; The GaN nanoparticle related peak with height of 12 nm at 355.5 nm is blue shifted to 349.8 nm as the height decreases to 6 nm. Accordingly, nanoparticles with different wavelengths are obtained by controlling the geometric size of nanoparticles in multiple quantum wells active layer structure by adjusting growing parameters, so that emitting wavelength of LED is easily modified.

Emitting wavelengths of nanoparticles is obtained by controlling elemental composition thereof, in addition to geometric size. Referring to InₓGa₁₋ₓN materials, for example, when In composition is changed from x=0 to x=1, the emitting wavelength expands from 362 nm UV to 1.6 μm far infrared. In Nichia's method in which light emitting diodes are made of GaN/InGaN multiple quantum wells, when InGaN is used as well layer material, the emitting wavelength of LED can be controlled by modification of In composition, and it was noted that In composition for emitting wavelength at 590 nm is 34%, for 525 nm is 29%, and for 450 nm is 17%. Therefore, in the present invention, emitting wavelengths of UV (<400 nm) to visible (400˜700 nm) to near infrared (0.7˜1.6 μm) are obtained by modifying in composition while growing nanoparticles with InGaN.

The technical content and process of the invention are described in the following embodiments.

### EXAMPLE 1

### Single-Wavelength LED Using Nanoparticle-Containing Active Layer

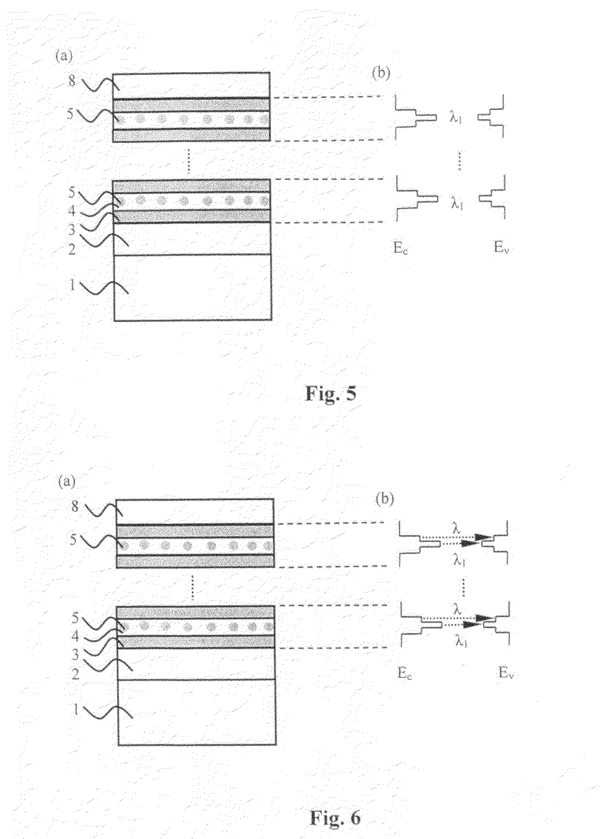

As to growth of nanoparticles in MQWs active layer structure effectively, which can reduce non-radioactive recombination rate resulted from dislocation in current MQWs active layers of Group III nitride LEDs, the present invention provides a nanoparticle-containing MQWs structure with single wavelength as active layer, as shown in FIG. 5(a), to elevate emitting efficiency of LEDs. The process comprises steps of, firstly providing a substrate 1 and growing n (or p) type buffer layer 2 on substrate 1, thereafter growing barrier layer 3; then growing lower energy well layer 4 and growing a nanoparticle structure with single wavelength λ₁ therein; further growing higher energy barrier layer 3 to complete the single layer quantum well containing nanoparticle structure as active layer. The emitting efficiency of LEDs can be elevated by repeatedly growing the above structure or adjusting growing parameters like temperature (density is lower when it is high), and finally, growing p (or n) type buffer layer.

FIG. 5(b) shows related energy bands of the nanoparticle-containing MQWs active layer with single wavelength. Under applied forward bias, minority carriers injected into lower energy well layer and emit light through recombination. The emitting wavelength λ₁ of the nanoparticles can be obtained by controlling the elemental composition and geometric size thereof.

### EXAMPLE 2

### Dichroic-Wavelengths LED Using Nanoparticle-Containing Active Layer

It is known from the above that the emitting wavelengths of the nanoparticles can be obtained by controlling the elemental composition and geometric size thereof. Accordingly, nanoparticles with different elemental composition and geometric size can be grown on different layers inside the MQWs active layer structure, and light emitting diodes with various wavelengths are manufactured. With the emitting properties of the nanoparticle-containing MQWs active layer, it is advantageous to develop white light emitting diodes with practical uses in the lighting applications.

Therefore, various designs of nanoparticle-containing MQWs structure as active layer are provided in the present invention to hybridize white light. Firstly, a design called “Dichroic wavelengths LED using nanoparticle-containing active layer” is described. Complementary colors generating white light under irradiation of D65 standard light source with color temperature of 6500 K, according to CIE, 1964, are shown in Table 1.

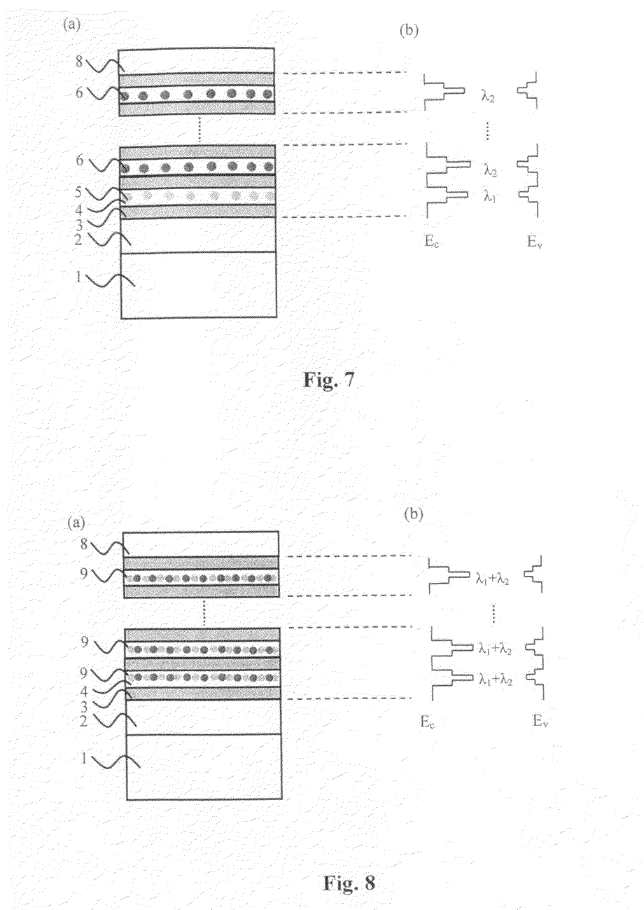

The structure view and related energy bands of said “pn junction light emitting diode having nanoparticle-containing MQWs structure with complementary dichroic wavelengths as active layer” are shown in FIGS. 6(a) and (b), respectively. The structure design is based on MQWs active layer, wherein each layer of quantum well comprises higher energy barrier layers 3 and lower energy well layers 4 with emitting wavelength λ as one of those listed in Table 1. Nanoparticles with emitting wavelength λ₁ as one of those listed in Table 1 are grown on first well layer 4, and MQWs active layer is grown by repeatedly growing a plurality of well and nanoparticles with wavelengths λ and λ₁ in this order. Moreover, other structure view and related energy bands of said “Dichroic wavelengths LED using nanoparticle-containing active layer” are shown in FIGS. 7(a) and (b), respectively. The structure design is based on MQWs active layer, wherein each layer of quantum well comprises higher energy barrier layers 3 and lower energy well layers 4. Nanoparticles with emitting wavelength λ₁ as one of those listed in Table 1 are grown on first well layer 4, nanoparticles with corresponding complementary wavelength λ₂ listed in Table 1 are grown on second well layer 4, and MQWs structure active layer is grown by repeatedly growing a plurality of nanoparticles with wavelengths λ₁ and λ₂ in this order. It is also possible to generate white light by growing a plurality of nanoparticle-containing MQWs structures with wavelength [symbol] 1, then growing a plurality of nanoparticle-containing MQWs structures with wavelength λ_{b 2}.

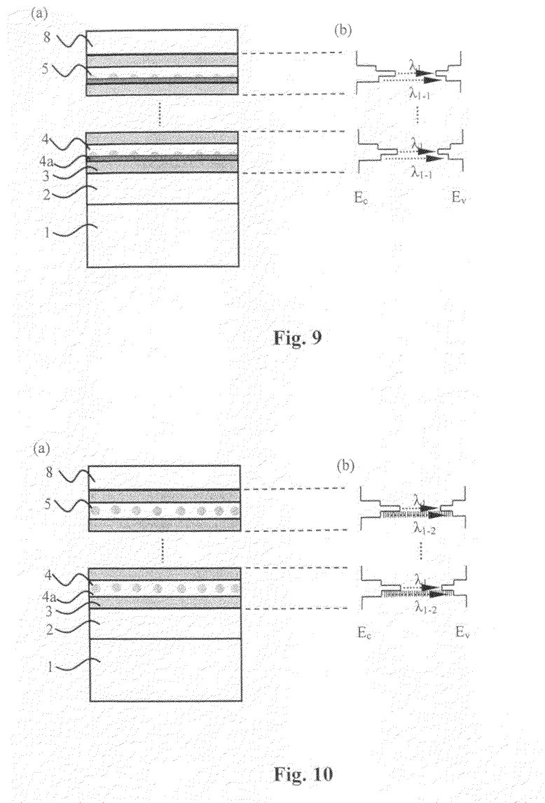

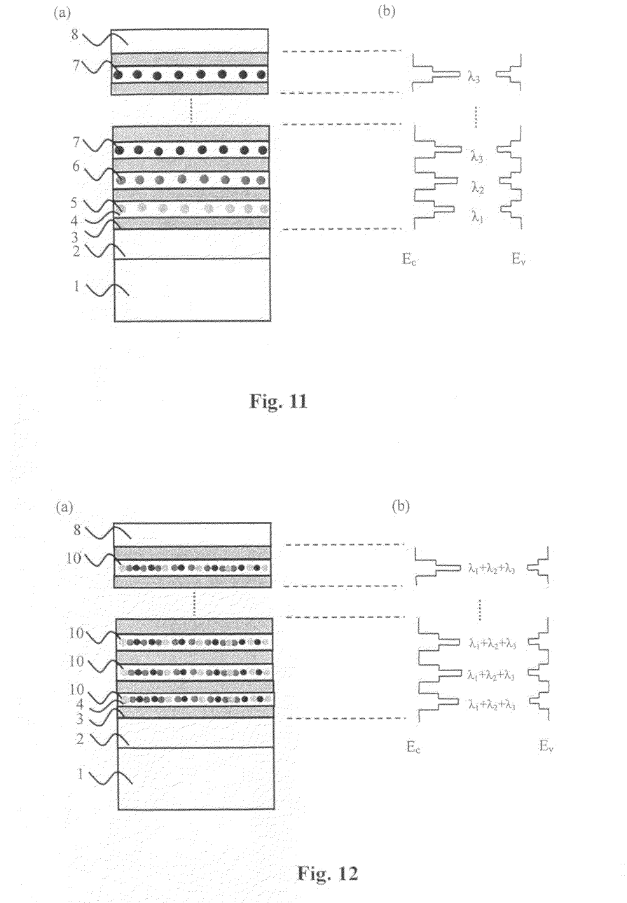

Also, “Dichroic wavelengths LED using nanoparticle-containing active layer” is provided in the present invention. The structure view and related energy bands thereof are shown in FIGS. 8(a) and (b), respectively. Nanoparticles with complementary dichroic wavelengths λ₁ and λ₂ are grown on the same well layer 4, and white light is generated by growing a plurality of nanoparticle-containing MQWs structures with complementary wavelengths λ₁ and λ₂ as active layer. The process of growing nanoparticle structure with complementary wavelengths in the same well layer can be achieved by phase separation commonly appearing in InGaN materials, i.e., InGaN nanoparticles with two In compositions or InGaN phase separation structure with two compositions in the well present in the same time. Also, “multiwavelength light emitting diode having nanoparticle-containing MQWs structure with complementary dichroic wavelengths as active layer” is provided in the present invention. The structure view and related energy bands thereof are shown in FIGS. 9(a) and (b), respectively. Nanoparticle structure 5 with wetting layer 4a is grown in the same well layer 4. The emitting wavelengths of the nanoparticle structure mainly consist of wavelengths from wetting layer (λ₁) and from nanoparticle themselves (λ₂), thus light with complementary dichroic wavelengths is generated. Nanoparticle structure with wetting layer can be grown with SK mode in the present invention, since it is necessary for SK mode to accumulate sufficient stress strain by wetting layer in order to grow from two-dimensionally to three-dimensionally. On the other hand, interface state is usually present at the interface between nanoparticles and well layer 4, well layer 4 and barrier layer 3, or nanoparticles and barrier layer 3. A lot of carriers emit through recombination of the interface state while entering well layer. Therefore, as shown in FIG. 10, light with complementary dichroic wavelengths is generated in one well layer 4 by combining wavelengths from interface state (λ₁₋₂) and from particles themselves (λ₁) in the present invention. In addition to interface state, it is also possible to dope impurities into nanoparticle structure and well layer to generate light with complementary dichroic wavelengths by combining wavelengths from impurity state and from particles themselves.

### EXAMPLE 3

### RGB LED Using Nanoparticle-Containing Active Layer

As white light hybridized through combination of the primary colors is of high color rendering, thus is advantageous, nanoparticle-containing MQWs structure with the primary color wavelengths as active layer is provided in the present invention, as shown in FIG. 11(a), to hybridize white light. The related energy bands are shown in FIG. 11(b). First (λ₁), second (λ₂) and third (λ₃) wavelengths denote individual color of the primary colors. Said nanoparticle-containing MQWs structure with the primary color wavelengths as active layer is produced by growing nanoparticles with first emitting wavelength (λ₁) in first well layer 4, growing nanoparticles with second emitting wavelength (λ₂) in second well layer 4, and growing nanoparticles with third emitting wavelength (λ₃) in third well layer 4, then repeatedly growing a plurality of nanoparticle-containing MQWs structures with wavelengths [symbol] 1, [symbol] ₂ and λ₃ in this order to hybridize white light. Another structure useful in hybridization of white light with the primary colors is provided in the present invention, as shown in FIG. 12(a). Nanoparticles with first (λ₁), second (λ₂) and third (λ₃) wavelengths are grown in the same well layer 4 of the MQWs active layer, and white light is generated through the combination of a plurality of said structures. The related energy bands are shown in FIG. 12(b). The above processes can obtain necessary wavelengths of the primary colors for hybridization of white light by controlling the elemental composition and geometric size of the nanoparticles. The emitting intensity is also controlled by adjusting growing parameters like temperature (density is high when it is low), so that higher emitting intensity is obtained with nanoparticles of high density. It is also possible to elevate emitting intensity with more layers of nanoparticles since the intensity difference of the individual color of the primary colors is balanced, so that white light emitting diode with more consistent color is manufactured.

The process of hybridizing white light as described in the present invention comprises steps of, controlling the elemental composition and geometric size of the nanoparticles in MQWs active layer to obtain wavelengths in red, green and blue regions, and combining these wavelengths. Only single light emitting diode is needed in the process to emit white light, therefore manufacturing cost is greatly reduced. Also, difficulty in achieving consistent color with three light emitting diodes, due to the different properties of each diode, is eliminated. Therefore, the present invention is novel and progressive in the manufacturing of white light emitting diodes.

### EXAMPLE 4

### Multi-Wavelength LED Using Nanoparticle-Containing Active Layer

Natural light and light from white heat bulb are of continuous spectrum. Current white light generated by triggering yellow phosphor particles with blue light emitting diode is based on full color presentation in complementary visible region, whose essential emitting wavelengths consist of blue and yellow band spectrum. Color distortion of objects occurs as said white light is lack of wavelengths in red region, so that color rendering of light source is even more important. For this reason, another process of hybridizing white light is provided in the present invention. That is, by controlling elemental composition or size, light emitting from nanoparticles in each quantum wells layer consist of three or more wavelengths including red, orange, yellow, green, cyan, blue, and violet (λ₁, λ₂, λ₃, λ₄, λ₅, λ₆, and λ₇). Therefore, full color white light with continuous spectrum is hybridized.

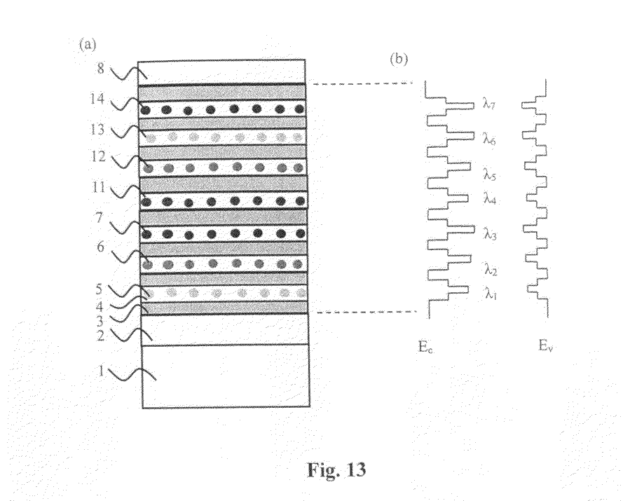

FIG. 13(a) shows the nanoparticle-containing MQWs active layer structure with multi-wavelengths as active layer in the present invention; and (b) shows related energy bands. Each quantum well layer comprises lower energy well layer 4 in which noparticles are mainly grown, and higher energy barrier layer 3. Also, nanoparticles with first wavelength (λ₁) are grown in first well layer 4, nanoparticles with second wavelength (λ₂) are grown in second well layer 4, nanoparticles with third wavelength (λ₃) are grown in third well layer 4, nanoparticles with fourth wavelength (λ₄) are grown in fourth well layer 4, nanoparticles with fifth wavelength (λ₅) are grown in fifth well layer 4, nanoparticles with sixth wavelength (λ₆) are grown in sixth well layer 4, and nanoparticles with seventh wavelength (λ₇) are grown in seventh well layer 4. White light is hybridized through combination of wavelengths with λ₁, λ₂, λ₃, λ₄, λ₅, λ₆, and λ₇. However, The sufficient number of color wavelength in the nanoparticle-containing MQWs active layer structure with multicolor wavelengths to hybridize white light is not limited to seven, as long as more than three.

### EXAMPLE 5

### Multi-Wavelength LED Using Nanoparticle-Containing Active Layer with One Particle Size

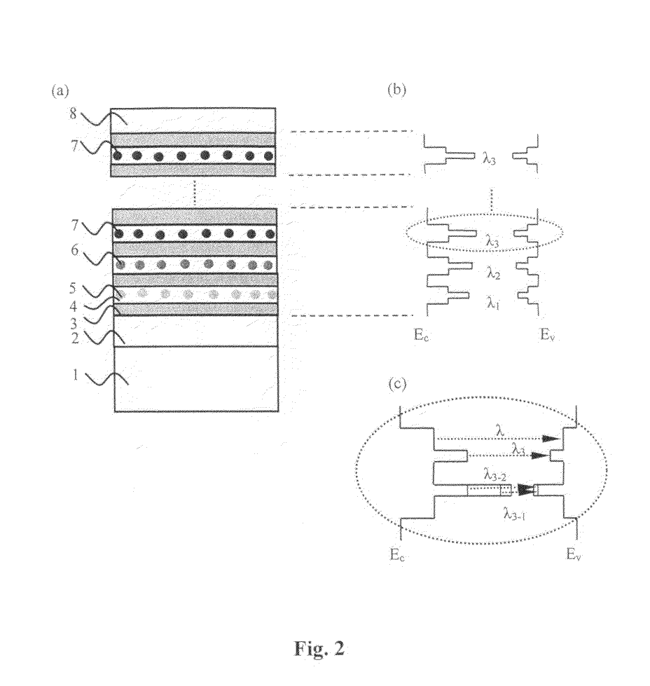

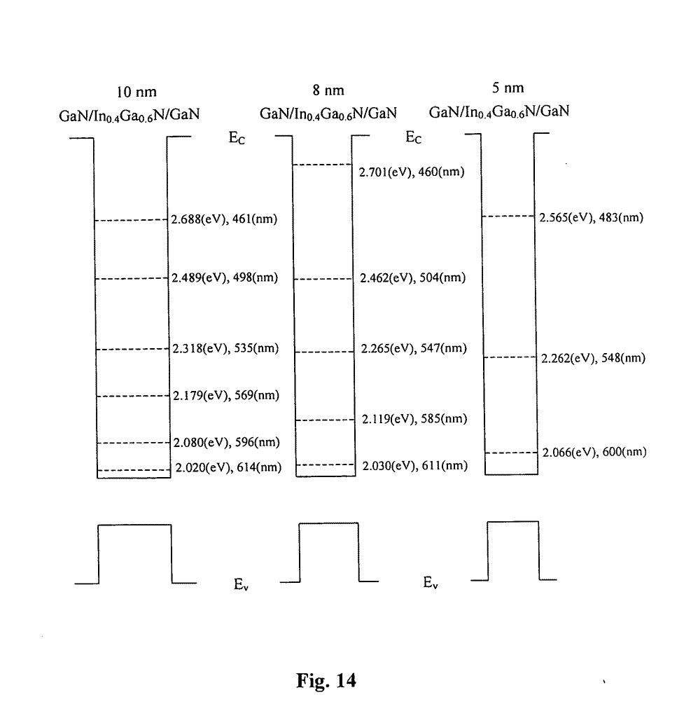

Prior to reaching quantum effect size, the energy level of nanoparticles is continuous and emit only single wavelength as λ₃ shown in FIG. 2(c). However, when the size is reduced to 10 nm or less, the energy level is quantized and more different energy levels are formed. It is possible that each separate quantized energy level is occupied by carriers, so that the recombination of carriers at different energy levels emits light with various wavelengths, for example, ground state wavelength λ₃₋₁ and excited state wavelength λ₃₋₂ as shown in FIG. 2(c). FIG. 14 is a schematic view showing separate energy levels and related emitting wavelengths of different sized InGaN nanoparticles with quantum effect grown in GaN quantum well. When InGaN nanoparticles consist of 40% In with size of 8 nm, the quantumized energy levels are 2.03 eV for ground state, 2.119 eV for first excited state, 2.265 eV for second excited state, 2.462 eV for third excited state, and 2.701 eV for fourth excited state. Namely, light emitting wavelengths of 611 nm (red), 585 nm, 547 nm (yellow), 504 nm and 460 nm (blue) is obtained. With this, single kind of nanoparticles emitting complementary dichroism, primary colors or multi wavelengths is obtained by growing different sized nanoparticles with quantum effect, accordingly white light is hybridized directly. Further, light emitting devices having nanoparticle-containing MQWs structure with multi wavelengths as active layer are manufactured by growing MQWs active layer and combining nanoparticles with different wavelengths in other layers.

### EXAMPLE 6

### Multi-Wavelength Phosphor Converted Led Pumped by UV Light Source

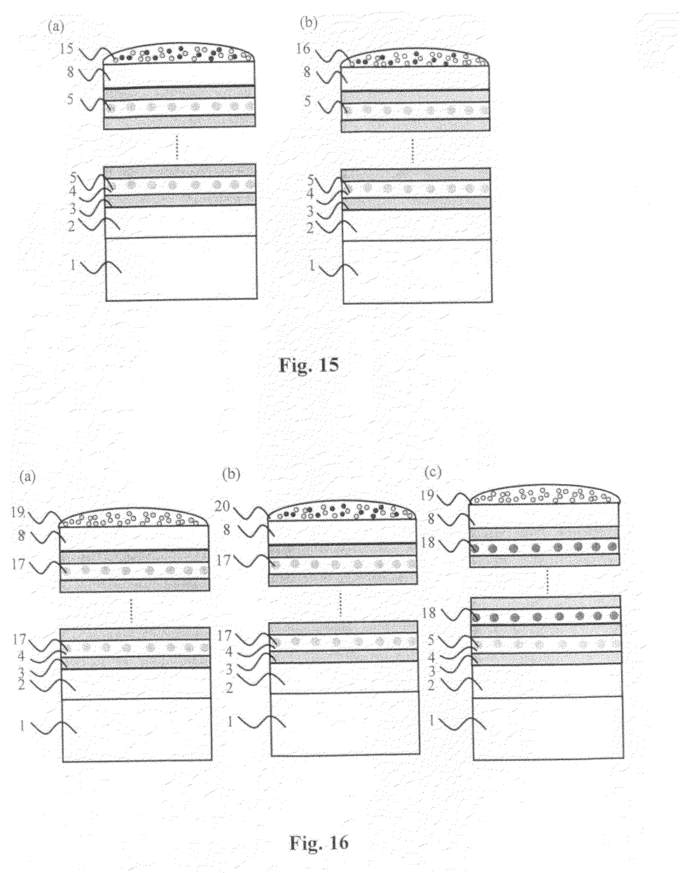

The present invention provides a multi-wavelength (including white light) light emitting device, comprising a UV light emitting component and phosphors capable of absorbing a part of light emitted by the UV light emitting component and emitting light of wavelength different from that of the absorbed light; wherein the active layer of LED contains nanoparticles. FIG. 15 shows a light emitting device structure provided in the present invention, wherein nanoparticle-containing light emitting diode with single UV wavelength is used to trigger (a) phosphors with complementary dichroism, or (b) phosphors with the primary colors. In this embodiment, the UV wavelength from the LED does not take part in the color combination, therefore the emitting wavelengths of the device are decided by the wavelength from the phosphors.

### EXAMPLE 7

### Multi-Wavelength Phosphor Converted Led Pumped by Visible Light Source

The present invention provides a multi-wavelength (including white light) light emitting device, comprising a visible light emitting component and phosphors capable of absorbing a part of light emitted by the visible light emitting component and emitting light of wavelength different from that of the absorbed light; wherein the active layer of LED contains nanoparticles. FIG. 16(a) shows a light emitting device structure provided in the present invention, wherein nanoparticle containing light emitting diode with a visible triggering wavelength (λ₁) is used to trigger phosphors with a phosphorescence wavelength (λ₂); said triggering wavelength λ₁ is in visible region (400 nm˜500 nm), and phosphorescence wavelength λ₂ is corresponding complementary color. FIG. 16(b) shows another light emitting device structure provided in the present invention, wherein nanoparticle-containing light emitting diode with an triggering wavelength (λ₁) is used to trigger phosphors with two phosphorescence wavelengths (λ₂ and λ₃); said triggering wavelength λ₁ , combining said phosphorescence wavelengths λ₂ and λ₃ are used as colors necessary for hybridizing white light. FIG. 16(c) shows a light emitting device structure provided in the present invention, wherein nanoparticle-containing light emitting diode with two triggering wavelengths (λ₁ and λ₂) is used to trigger phosphors with a phosphorescence wavelength (λ₃); said first and second triggering wavelengths λ₁ and λ₂ combining said phosphorescence wavelength λ₃ are used as colors necessary for hybridizing white light. In this embodiment, the number of phosphorescence wavelengths of the phosphors is not limited to two or less, and phosphors with two or more phosphorescence wavelengths are useful. Also, the number of triggering wavelengths is not limited to one or two, and two or more triggering wavelengths are useful to combine with the applied phosphorescence.

The present invention is disclosed above with reference to the preferable embodiments, however, the embodiments are not used as limitation of the present. It is appreciated to those in this field that the variation and modification directed to the present invention not apart from the spirit and scope thereof can be made, and the scope of the present invention is covered in the attached claims.

TABLE 1
Corresponding wavelength of the white light generated with
complementary colors according to D₆₅ standard light source

| | |
|---|---|
| Wavelength of the | Ratio of energy |
| complementary colors | levels |

| λ₁ (nm) | λ₂ (nm) | P(λ₂)/P(λ₁) |
|---|---|---|
| 380 | 560.9 | 0.000642 |
| 400 | 561.1 | 0.0785 |
| 420 | 561.7 | 0.891 |
| 440 | 562.9 | 1.79 |
| 460 | 565.9 | 1.53 |
| 480 | 584.6 | 0.562 |
| 484 | 602.1 | 0.44 |
| 486 | 629.6 | 0.668 |

1-24. (canceled)

25. A process for manufacturing electrical drived, multi-wavelength pn junction, organic or inorganic light emitting device, which comprises:
(1) growing n or p type buffer layer 2 on substrate 1;
(2) growing multi-stacked active layer structure comprising a plurality of higher energy bandgap barrier layers 3 and a plurality of lower energy bandgap well layers 4 on buffer layer 2;
(3) growing nanoparticles in some (or all) stacked layers in the structure;
(4) growing p or n type conductive layer 8; and
(5) producing electrodes on the p or n type conductive layer.

26. A process for manufacturing electrical drived, multi-wavelength organic or inorganic light emitting device, wherein the light emitting device comprising light emitting diode with nanoparticle structure and phosphor, which comprises:
(1) growing n or p type buffer layer 2 on substrate;
(2) growing multi-stacked active layer structure comprising higher energy bandgap barrier layers and lower energy bandgap well layers on buffer layer;
(3) growing nanoparticles in some (or all) stacked layers in the structure;
(4) growing p or n type conductive layer 8; and
(5) combining phosphors emitting at least one or more phosphorescences.

27. The process as described in claim 25, wherein emitting wavelengths from the multi-stacked active layer comprising or not comprising nanoparticles are in the range of 100 nm to 20 μm, including full color white light (400-700 nm), UV (<400 nm), and infrared (>700 nm).

28. The process as described in claim 25, wherein the multi-stacked active layer structure is selected from one of single hetero-junction, dual hetero-junction, single quantum well structure and multiple quantum wells structure.

29. The process as described in claim 25, wherein the materials suitable for the multi-stacked active layer and nanoparticles therein are selected from GaAs, InAs, InP, InSb, GaSb, InAGaN, InN, AlN, ZnSe, ZnTe, CdSe, CdTe, HgTe, HgSe, SiGe, SiC, InₓGa₁₋ₓN, InₓGa₁₋ₓP, InₓGa₁₋ₓAs, AlₓIn₁₋ₓN, AlₓIn₁₋ₓP, AlₓIn₁₋ₓAs, AlₓGa₁₋ₓN, AlₓGa₁₋ₓP, AlₓGa₁₋ₓAs, ZnₓCd₁₋ₓSe, ZnₓCd₁₋ₓTe, (AlₓGa₁₋ₓ)_{y}In_{1-y}N, (AlₓGa₁₋ₓ)_{y}In_{1-y}P, in which 0<x<1; 0<y<1.

30. The process as described in claim 25, wherein the phosphors suitable in the light emitting device are yellow: Y₃Al₅O₁₂:Ce³⁺, yellow: Y₃Al₅O₁₂:Eu²⁺, yellow: Y₃Al₁₅O₁₂:Eu²⁺, red: SrSiAl₂O₃N₂:Eu²⁺, red: SrS:Eu²⁺, red: Gd₂O₃S :Eu³⁺, red: Mg₄(F)GeO₅:Mn, red: SrS:Eu²⁺, green: SrAlSCISi:Eu, green: SrGa₂S₄:Eu²⁺, green: CuAuAl:ZnS, green: CuAl:ZnS, green: SrGa₂S₄:Eu²⁺, blue: SCAP, blue: AgZnS, blue: BaMgAl₁₀O₁₇:Eu²⁺, etc.

31. The process as described in claim 25, wherein the thicknesses of the lower energy bandgap well layers of the multi-stacked active layer structure are in the range of 0.3 nm˜1 μm, and that of higher energy bandgap barrier layers are in the range of 1 nm˜1 μm.

32. The process as described in claim 25, wherein the density of the emitting nanoparticles in the multi-stacked active layer ranges 10³˜10¹³ cm⁻² or higher.

33. The process as described in claim 25, wherein the thicknesses of the emitting nanoparticles in the multi-stacked active layer ranges 0.3˜100 nm, and the width thereof ranges 0.3˜500 nm.

34. The process as described in claim 25, wherein the nanoparticles can be grown among well layers, or above, below the interfaces of well layers and barrier layers.

35. The process as described in claim 25, wherein the wavelengths from the nanoparticles in the multi-stacked active layer can be obtained by controlling the elemental composition and geometric size thereof.

36. The process as described in claim 25, wherein the wavelengths from the nanoparticles in the multi-stacked active layer comprise wavelengths from the wetting layers and from nanoparticles themselves.

37. The process as described in claim 25, wherein the wavelengths from the nanoparticles in the multi-stacked active layer comprise wavelengths from phase separation structures inside barrier layers, well layers, and nanoparticles.

38. The process as described in claim 25, wherein the wavelengths from the multi-stacked active layer comprise wavelengths from interface states of barrier layers and well layers, nanoparticles and well layers, nanoparticles and barrier layers, and wetting layers and well layers.

39. The process as described in claim 25, wherein the wavelengths from the multi-stacked active layer comprise wavelengths from impurity states of barrier layers, well layers and nanoparticle structures.

40. The process as described in claim 25, wherein single kind of nanoparticles in the multi-stacked active layer, when has quantum effect size, emits one or more wavelengths through energy transitions among ground state, first excited state, second excited state or higher excited states.

41. The process as described in claim 25, wherein the wavelengths from the nanoparticles in the multi-stacked active layer can be single wavelength.

42. The process as described in claim 25, wherein the wavelengths from the multi-stacked active layer comprise parts (or all) of the emitting wavelengths come from the stack layers containing nanoparticles, and parts (or all) of the emitting wavelengths come from the stack layers not containing nanoparticles, so that complementary dichroic wavelengths are emitted and white light is hybridized; wherein nanoparticles in the stacked layers are grown in the same layer or two or more layers.

43. The process as described in claim 25, wherein the wavelengths from the multi-stacked active layer comprise parts (or all) of the emitting wavelengths come from the stack layers containing nanoparticles, and parts (or all) of the emitting wavelengths come from the stack layers not containing nanoparticles, so that three or more wavelengths, including the primary colors, and white light with continuous spectrum is hybridized; in which nanoparticles in the stacked layers are grown in the same layer or two or more layers to emit the same or different wavelengths.

44. The process as described in claim 25, wherein the nanoparticles in the multi-stacked active layer comprise those emit one or more wavelengths in the same well layer.

45. The process as described in claim 26, wherein the wavelengths from multi-stacked active layer comprise one or more UV wavelengths to trigger phosphors with complementary dichroic phosphorescence, the primary colors or multi phosphorescences to emit white light.

46. The process as described in claim 26, wherein the wavelengths from multi-stacked active layer comprise one or more visible wavelengths, in which at least one being used to trigger phosphors with multi phosphorescences, and wavelengths from multi-stacked active layer can combine the phosphorescences to emit white light with complementary dichroism, the primary colors or multi wavelengths.

47. The process as described in claim 26, wherein the wavelengths from multi-stacked active layer comprise one or more UV wavelengths, in which at least one being used to trigger phosphors with multi phosphorescences, and wavelengths from multi-stacked active layer can combine the phosphorescences to emit white light with complementary dichroism, the primary colors or multi wavelengths. (currently amended).

48. The process as described in claim 25, wherein flip-chip stacking, trimmed reverse pyramid and surface roughing are useful to elevate the take-out efficiency and the light emitting efficiency of the devices.

49. The process as described in claim 25, wherein the light emitting device can be light emitting diode and laser diode, including resonant cavity light emitting diodes, surface-emitting light emitting diodes, edge-emitting light emitting diodes, surface-emitting laser diodes, and edge-emitting laser diodes.

50. The process as described in claim 25, wherein the light emitting diode is of pn diode or Schottky diode structure.

51. The process as described in claim 26, wherein emitting wavelengths from the multi-stacked active layer comprising or not comprising nanoparticles are in the range of 100 nm to 20 μm, including full color white light (400-700 nm), UV (<400 nm), and infrared (>700 nm).

52. The process as described in claim 26, wherein the multi-stacked active layer structure is selected from one of single hetero-junction, dual hetero-junction, single quantum well structure and multiple quantum wells structure.

53. The process as described in claim 26, wherein the materials suitable for the multi-stacked active layer and nanoparticles therein are selected from GaAs, InAs, InP, InSb, GaSb, InAGaN, InN, AlN, ZnSe, ZnTe, CdSe, CdTe, HgTe, HgSe, SiGe, SiC, InₓGa₁₋ₓN, InₓGa₁₋ₓP, InₓGa₁₋ₓAs, AlₓIn₁₋ₓN, AlₓIn₁₋ₓP, AlₓIn₁₋ₓAs, AlₓGa₁₋ₓN, AlₓGa₁₋ₓP, AlₓGa₁₋ₓAs, ZnₓCd₁₋ₓSe, ZnₓCd₁₋ₓTe, (AlₓGa₁₋ₓ)_{y}In_{1-y}N, (AlₓGa₁₋ₓ)_{y}In_{1-y}P, in which 0<x<1; 0<y<1.

54. The process as described in claim 26, wherein the phosphors suitable in the light emitting device are yellow: Y₃Al₅O₁₂:Ce³⁺, yellow: Y₃Al₅O₁₂:Eu²⁺, yellow: Y₃Al₁₅O₁₂:Eu²⁺, red: SrSiAl₂O₃N₂:Eu²⁺, red: SrS:Eu²⁺, red: Gd₂O₃S:Eu³⁺, red: Mg₄(F)GeO₅:Mn, red: SrS:Eu²⁺, green: SrAlSCISi:Eu, green: SrGa₂S₄:Eu²⁺, green: CuAuAl:ZnS, green: CuAl:ZnS, green: SrGa₂S₄:Eu²⁺, blue: SCAP, blue: AgZnS, blue: BaMgAl₁₀O₁₇:Eu²⁺, etc.

55. The process as described in claim 26, wherein the thicknesses of the lower energy bandgap well layers of the multi-stacked active layer structure are in the range of 0.3 nm˜1 μm, and that of higher energy bandgap barrier layers are in the range of 1 nm˜1 μm.

56. The process as described in claim 26, wherein the density of the emitting nanoparticles in the multi-stacked active layer ranges 10³˜10¹³ cm⁻² or higher.

57. The process as described in claim 26, wherein the thicknesses of the emitting nanoparticles in the multi-stacked active layer ranges 0.3˜100 nm, and the width thereof ranges 0.3˜500 nm.

58. The process as described in claim 26, wherein the nanoparticles can be grown among well layers, or above, below the interfaces of well layers and barrier layers.

59. The process as described in claim 26, wherein the wavelengths from the nanoparticles in the multi-stacked active layer can be obtained by controlling the elemental composition and geometric size thereof.

60. The process as described in claim 26, wherein the wavelengths from the nanoparticles in the multi-stacked active layer comprise wavelengths from the wetting layers and from nanoparticles themselves.

61. The process as described in claim 26, wherein the wavelengths from the nanoparticles in the multi-stacked active layer comprise wavelengths from phase separation structures inside barrier layers, well layers, and nanoparticles.

62. The process as described in claim 26, wherein the wavelengths from the multi-stacked active layer comprise wavelengths from interface states of barrier layers and well layers, nanoparticles and well layers, nanoparticles and barrier layers, and wetting layers and well layers.

63. The process as described in claim 26, wherein the wavelengths from the multi-stacked active layer comprise wavelengths from impurity states of barrier layers, well layers and nanoparticle structures.

64. The process as described in claim 26, wherein single kind of nanoparticles in the multi-stacked active layer, when has quantum effect size, emits one or more wavelengths through energy transitions among ground state, first excited state, second excited state or higher excited states.

65. The process as described in claim 26, wherein the wavelengths from the nanoparticles in the multi-stacked active layer can be single wavelength.

66. The process as described in claim 26, wherein the wavelengths from the multi-stacked active layer comprise parts (or all) of the emitting wavelengths come from the stack layers containing nanoparticles, and parts (or all) of the emitting wavelengths come from the stack layers not containing nanoparticles, so that complementary dichroic wavelengths are emitted and white light is hybridized; wherein nanoparticles in the stacked layers are grown in the same layer or two or more layers.

67. The process as described in claim 26, wherein the wavelengths from the multi-stacked active layer comprise parts (or all) of the emitting wavelengths come from the stack layers containing nanoparticles, and parts (or all) of the emitting wavelengths come from the stack layers not containing nanoparticles, so that three or more wavelengths, including the primary colors, and white light with continuous spectrum is hybridized; in which nanoparticles in the stacked layers are grown in the same layer or two or more layers to emit the same or different wavelengths.

68. The process as described in claim 26, wherein the nanoparticles in the multi-stacked active layer comprise those emit one or more wavelengths in the same well layer.

69. The process as described in claim 26, wherein flip-chip stacking, trimmed reverse pyramid and surface roughing are useful to elevate the take-out efficiency and the light emitting efficiency of the devices.

70. The process as described in claim 26, wherein the light emitting device can be light emitting diode and laser diode, including resonant cavity light emitting diodes, surface-emitting light emitting diodes, edge-emitting light emitting diodes, surface-emitting laser diodes, and edge-emitting laser diodes.

71. The process as described in claim 26, wherein the light emitting diode is of pn diode or Schottky diode structure.
